(19) United States
(12) Patent Application Publication
(10) Pub. No.: US 2009/0097521 A1
(43) Pub. Date: Apr. 16, 2009

(54) Side Surface Light Emitting Semiconductor Element And Method Of Manufacturing The Same

(75) Inventor: Ken Nakahara, Kyoto (JP)

Correspondence Address: RABIN & Berdo, PC, 1101 14TH STREET, NW, SUITE 500, WASHINGTON, DC, 20005, US

(73) Assignee: ROHM CO., LTD., Kyoto-fu (JP)

(21) Appl. No.: 12/225,095

(22) PCT Filed: Mar. 15, 2007
(86) PCT No.: PCT/JP2007/055203

§ 371 Date: Sep. 12, 2008

(30) Foreign Application Priority Data
Mar. 15, 2006 (JP) 2006-071481

(51) Int. Cl. H01S 5/18; H01L 21/02

(52) U.S. Cl. 372/46.01; 438/39; 257/E21.002

(57) ABSTRACT

A side surface light emitting semiconductor element includes: an AlGaN layer doped with Mg at a concentration equal to or less than 5×10¹⁹ cm⁻³; a ridge having a striped shape and formed in an upper portion of a laminated structure which includes the AlGaN layer and an active layer; and a Schottky barrier formed on a top surface of the laminated structure in an area where the ridge is not formed and the AlGaN layer is exposed.

### TECHNICAL FIELD

The present invention relates to a side surface light emitting semiconductor element and a method of manufacturing the same.

### BACKGROUND ART

Heretofore, a light emitting semiconductor element has been used for a display device for displaying images. Typical examples of such light emitting semiconductor elements include a light emitting semiconductor element used in a dot matrix display device, a light emitting semiconductor element used in a backlight of a liquid crystal display device for a mobile phone and a light emitting semiconductor element used in a backlight of a liquid crystal display device for a TV set, and the like.

For example, in the dot matrix display device, light emitting semiconductor elements of red LEDs (Light Emitting Diodes), green LEDs, and blue LEDs are disposed side by side.

In the liquid crystal display device for the mobile phone, light emitting semiconductor elements of blue LEDs and yellow LEDs are disposed as a backlight. The liquid crystal display device for the mobile phone generates a white light by using these light emitting semiconductor elements of blue and yellow LEDs.

In the liquid crystal display device for the TV set, light emitting semiconductor elements of red LEDs, green LEDs and blue LEDs are disposed side by side as a backlight. In the liquid crystal display device for the TV set, a larger number of green LEDs are used than red and blue LEDs.

In order to increase an energy efficiency in such display devices and the like, a light emitting semiconductor element which emits light from a local area therein has been required.

As such light emitting semiconductor elements, generally known is a side surface light emitting semiconductor element which is provided with a ridge having a striped shape and formed in the upper portion of a laminated structure which includes an active layer.

Specifically, as shown in FIG. 8, a side surface light emitting semiconductor element is provided with an n-type nitride semiconductor layer (layers from an n-type contact layer 502 to a light guide layer 504), an MQW active layer 506 and a p-type nitride semiconductor layer (layers from a p-type first light guide layer 507 to a p-type contact layer 510). A ridge having a striped shape is formed in the p-type nitride semiconductor layer.

The side surface light emitting semiconductor element has a structure in which all the exposed surfaces of the ridge are covered with an insulation film 515 except the top surface of the p-type contact layer 510 which is electrically connected to a p-electrode 513 (refer to Japanese Patent Application Publication No. 2001-15851, for example).

In order to manufacture such a side surface light emitting semiconductor element, firstly, a ridge having a striped shape is formed in the p-type nitride semiconductor layer, and an insulation film 515 is subsequently formed on the ridge.

Secondly, the insulation film 515 formed over the p-type contact layer 510, which is an upper portion of the ridge, is removed, and the p-electrode 513 is formed at least on the exposed surface of the p-type contact layer 510. Thereby a side surface light emitting semiconductor element can be manufactured.

According to this side surface light emitting semiconductor element, when a current flows between the p-electrode 513 and an n-electrode 514, holes from the p-electrode 513 concentratedly flow through the ridge and an area of the MQW active layer 506 lying under the ridge. As a result, holes and electrons can be recoupled in the area of the MQW active layer 506 lying under the ridge, thereby light is emitted. Thus, the side surface light emitting semiconductor element can emit light from a local area.

Such a side surface light emitting semiconductor element can achieve a large current constriction effect, a large current confinement effect and a large light confinement effect, and therefore generally valued as a structure offering high energy efficiency.

However, in the method of manufacturing a conventional side surface light emitting semiconductor element as described above, it is difficult to remove only the insulation film 515 formed over the p-type contact layer 510, which is an upper portion of the ridge. Thus, the conventional method has a problem that production yield cannot be improved.

### DISCLOSURE OF THE INVENTION

A first aspect of a side surface light emitting semiconductor element according to the present invention is summarized as including: an AlGaN layer doped with Mg at a concentration equal to or less than 5×10¹⁹ cm⁻³; a ridge having a striped shape and formed in an upper portion of a laminated structure which includes the AlGaN layer and an active layer; and a Schottky barrier formed on a top surface of the laminated structure in an area where the ridge is not formed and the AlGaN layer is exposed.

According to this aspect, provided are a ridge having a striped shape and formed in an upper portion of the laminated structure which includes the p-type clad layer and the MQW active layer, and a Schottky barrier formed on a top surface of the laminated structure in an area where the ridge is not formed and the clad layer is exposed. According to this structure, in the ridge structure, removing only a part of an insulation film to be in ohmic contact with the p-electrode 113 is not required. Thus, a production yield can be improved.

Further, the AlGaN having a wide band gap energy, is doped with Mg at a concentration equal to or less than 5×10¹⁹ cm⁻³. This reduces the concentration of the holes and makes it more difficult for the holes to flow from the Schottky barrier to the AlGaN layer, resulting in an increased resistance between the Schottky barrier and the AlGaN layer. Accordingly, the holes tend to flow only through the ridge in the side surface light emitting semiconductor element. Therefore, a current constriction effect, a current confinement effect and a light confinement effect can be achieved in the ridge, and emitting light from the active layer having a small area can be realized.

Thus, the side surface light emitting semiconductor element which emits light from a local area and has a simple structure and a high production yield can be obtained.

In the first aspect of the present invention, an upper portion of the ridge may be a GaN layer doped with Mg at a concentration equal to or more than 1×10¹⁹ cm⁻³.

According to this aspect, since the upper portion of the ridge is the GaN layer doped with Mg at a concentration equal to or more than 1×10¹⁹ cm⁻³, the concentration of electrons in the upper portion of the ridge can be increased to further improve the current constriction effect of the ridge.

In the first aspect of the present invention, the side surface light emitting semiconductor element may further include a metallic layer composed of Pd or Ni and formed on the ridge and on at least a part of the Schottky barrier.

According to this aspect, the metallic layer composed of Pd or Ni and formed on the ridge and on at least the part of the Schottky barrier is provided. This makes it possible to obtain an electrode which easily takes an ohmic characteristic to the AlGaN layer and GaN layer. Thus, the holes can easily be flow through the upper portion of the ridge, and the current constriction effect of the ridge can further be improved.

A second aspect of the present invention is summarized as a method of manufacturing a side surface light emitting semiconductor element, including: forming a ridge having a striped shape, on an upper portion of a laminated structure which includes an active layer and an AlGaN layer doped with Mg at a concentration equal to or less than 5×10¹⁹ cm⁻³; by performing a dry-etching utilizing an ion impact, and forming a Schottky barrier, on a top surface of the laminated structure in an area where the ridge is not formed and the AlGaN layer is exposed, by performing the dry-etching utilizing the ion impact.

According to this aspect, the ridge is formed in the upper portion of the laminated structure which includes the active layer and the AlGaN layer composed of AlGaN doped with Mg at a concentration equal to or less than 5×10¹⁹ cm⁻³. Further, an appropriate damage is applied, by performing the dry-etching utilizing the ion impact, on the top surface of the laminated structure in an area where the ridge is not formed and the AlGaN clad layer is exposed. Thus, an n-type inversion layer (i.e., the Schottky barrier), in which the holes have difficulty in flowing, is formed. Thus, the resistance between the Schottky barrier and the AlGaN layer is increased whereby the holes easily flow through only the ridge. Therefore, a current constriction effect, a current confinement effect and a light confinement effect can be achieved in the ridge, and emitting light from a small area of the active layer can be realized.

Thus, the side surface light emitting semiconductor element which has a high production yield and emits light from a local area can be manufactured.

### BRIEF DESCRIPTION OF DRAWINGS

FIG. 1 shows a cross-sectional structure of a side surface light emitting semiconductor element according to an embodiment of the present invention.

FIG. 2 is a flowchart showing a method of manufacturing the side surface light emitting semiconductor element according to the embodiment of the present invention.

FIG. 3 is a cross-sectional view of the side surface light emitting semiconductor element after carrying out a laminating process in the method of manufacturing the side surface light emitting semiconductor element according to the embodiment of the present invention.

FIG. 4 is a cross-sectional view of the side surface light emitting semiconductor element in a stripe pattern forming process in the method of manufacturing the side surface light emitting semiconductor element according to the embodiment of the present invention.

FIG. 5 is a cross-sectional view of the side surface light emitting semiconductor element in a ridge forming process in the method of manufacturing the side surface light emitting semiconductor element according to the embodiment of the present invention.

FIG. 6 shows the cross-section structure of an ICP etcher used in the ridge forming process and Schottky barrier forming processes in the method of manufacturing the side surface light emitting semiconductor element according to the embodiment of the present invention.

FIG. 7 is a cross-sectional view of the side surface light emitting semiconductor element after carrying out an electrode forming process in the method of manufacturing the side surface light emitting semiconductor element according to the embodiment of the present invention.

FIG. 8 shows the cross section structure of the semiconductor light emitting element according to the prior art.

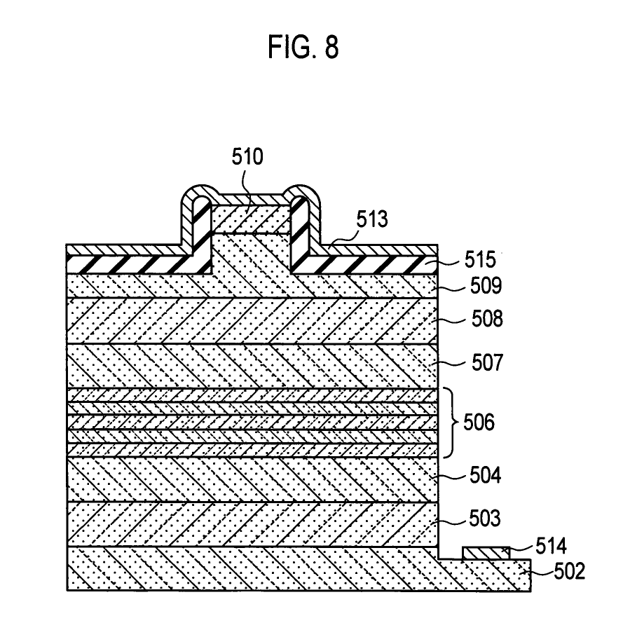

### BEST MODE FOR CARRYING OUT THE INVENTION

The embodiments of the present invention are described with reference to the accompanying drawings. In the description of the following drawings, the same or similar parts are denoted by the same or similar symbols. However, it should be noted that the drawings are diagrammatical and each dimension ratio is different from the actual one.

Therefore, the following description should be taken into consideration to judge specific dimensions and the like. Also, a part in which dimensional relationship and ratio are different between drawings is of course included.

### (Configuration of the Side Surface Light Emitting Semiconductor Element According to the Embodiment of the Present Invention)

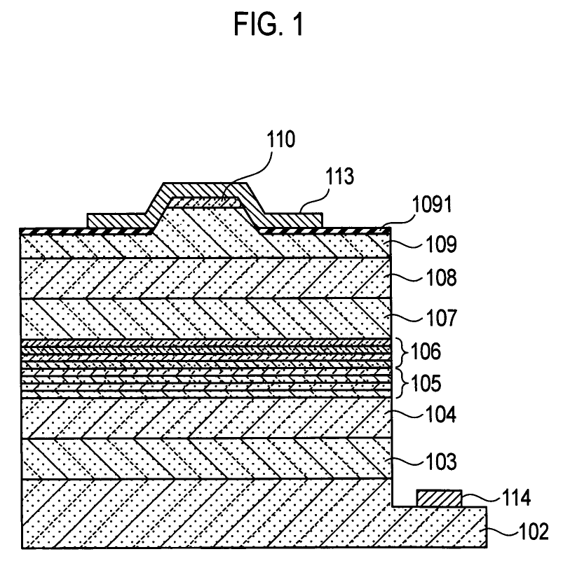

With reference to FIG. 1, the configuration of the side surface light emitting semiconductor element according to the embodiment of the present invention is described. FIG. 1 shows a cross section configuration of the side surface light emitting semiconductor element of the present embodiment. As an example of the side surface light emitting semiconductor element of the present embodiment, description is given of a side surface light emitting type LED (Light Emitting Diode) emitting blue light.

As shown in FIG. 1, the side surface light emitting semiconductor element of the present embodiment has a laminated structure which includes an n-type contact layer 102, an n-type clad layer 103, an n-type light guide layer 104, an n-type superlattice layer 105, an MQW active layer 106, a p-type first light guide layer 107, a p-type second light guide layer 108, a p-type clad layer 109 and a p-type contact layer 110. A ridge having a striped shape is formed in the upper portion of the aforementioned laminated structure (i.e. on a part of the p-type clad layer 109 and on the p-type contact layer 110).

An n-electrode 114 is formed on the main surface of the n-type contact layer 102, by a multilayer metallic film of Al/Ti/Au. The n-electrode 114 may also be formed of a multilayer metallic film of Al/Ni/Au or Al/Pd/Au.

A p-type electrode 113 is formed of Pd layer and Au layer which are laminated sequentially on at least a part of a Schottky barrier 1091 and on the ridge, and is in ohmic contact with the p-type contact layer 110. The p-type electrode 113 may be formed of Ni and Au layers, by laminating the Ni layer in place of Pd layer.

The n-type contact layer 102 is formed of Si-doped GaN.

The n-type clad layer 103 is formed of Si-doped Al_{0.05}GaN. The n-type light guide layer 104 is formed of undoped GaN. The n-type superlattice layer 105 has a superlattice structure formed by alternately laminating InGaN layers and GaN layers. The InGaN layers and GaN layers each has a thickness of equal to or less than 30 nm.

The MQW active layer 106 has a multi quantum well structure formed of a nitride semiconductor containing In.

Specifically, the MQW active layer 106 has an MQW structure in which a well layer formed of In_{0.17}GaN with a thickness of 3 nm and a barrier layer formed of undoped GaN with a thickness of 10 nm are alternately laminated eight times, respectively.

The p-type first light guide layer 107 is formed of undoped GaN or In_{0.01}GaN containing about 1% of In.

The p-type second light guide layer 108 is formed of undoped GaN.

The p-type clad layer 109 is formed of Al_{X}Ga_{1-X}N (0≦X≦0.5) doped with Mg at a concentration equal to or less than 5×10¹⁹ cm⁻³. Note that the concentration of Mg in the p-type clad layer 109 is preferably equal to or more than 1×10¹⁸ cm⁻³. By using the p-type clad layer having the Mg concentration equal to or more than 1×10¹⁸ cm⁻³, the p-type clad layer 109 can flow increased amount of holes from the p-type contact layer 110 therethrough.

The p-type contact layer 110 is formed of GaN doped with Mg at a concentration equal to or more than 1×10¹⁹ cm⁻³. The concentration of Mg in the p-type contact layer 110 is preferably not less than 5×10¹⁹ cm⁻³ and not more than 5×10²⁰ cm⁻³. If the concentration of Mg is more than 5×10²⁰ cm⁻³ in the p-type contact layer 110, Mg doped therein may break the a GaN crystal.

The Schottky barrier 1091 is formed on the top surface of the p-type clad layer 109 in an area where the p-type contact layer 110 is not formed. Therefore, a part of the top surface of the p-type clad layer 109 on which the p-type contact layer 110 is not formed is in Schottky-contact with the p-electrode 113.

The p-type contact layer 110 forms the ridge having a striped shape together with a part of the p-type clad layer 109. The top surface of the p-type contact layer 110 is in ohmic contact with the p-electrode 113.

### (Method of Manufacturing the Side Surface Light Emitting Semiconductor Element According to the Embodiment of the Present Invention)

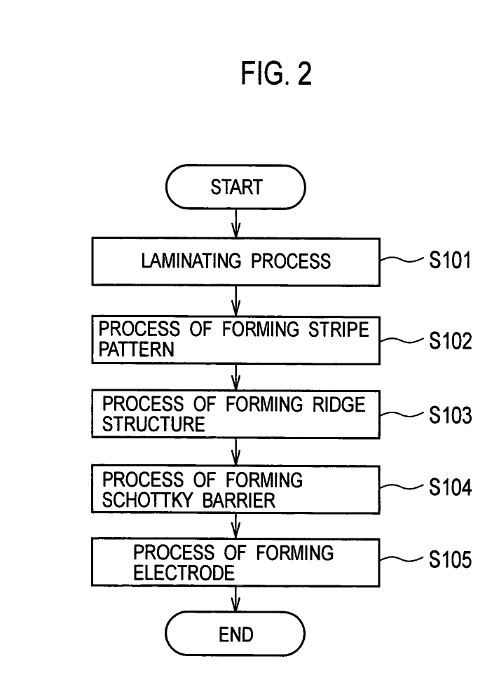

With reference to FIGS. 2 to 7, processes performed in the method of manufacturing the side surface light emitting semiconductor element of the present embodiment is described below.

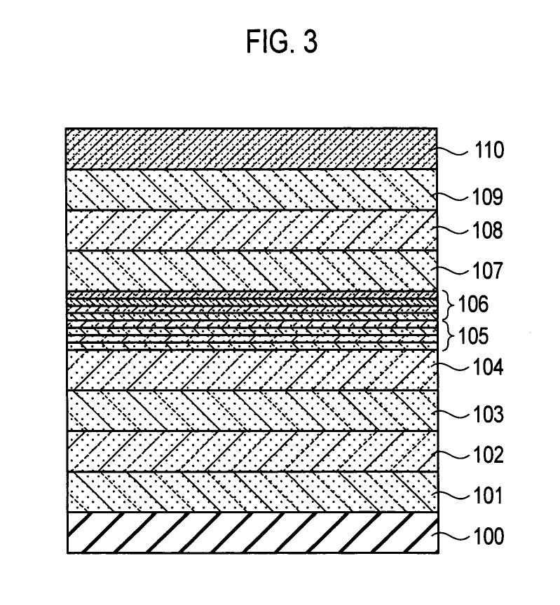

As shown in FIGS. 2 and 3, in step S101, a laminating process is performed in which the crystals of the n-type buffer layer 101, the n-type contact layer 102, the n-type clad layer 103, the n-type light guide layer 104, the n-type superlattice layer 105, the MQW active layer 106, the p-type first light guide layer 107, the p-type second light guide layer 108, the p-type clad layer 109 and the p-type contact layer 110 are sequentially formed by a crystal growth (epitaxial growth) on a substrate formed of sapphire (hereinafter, referred to as substrate 100).

Specifically, in the present embodiment, the substrate 100 is firstly put in an MOCVD (Metal Organic Chemical Vapor Deposition) system, and a thermal cleaning is performed on the substrate 100 by increasing the temperature to approximately 1050° C. while causing hydrogen gas to flow.

Secondly, the temperature inside the MOCVD system is reduced to approximately 600° C., and forms, by an epitaxial growth (hereinafter, simply referred to as crystal growth), an n-type buffer layer 101 composed of GaN, on the substrate 100.

Thirdly, the temperature inside the MOCVD system is again increased to approximately 1000° C., and sequentially forms the n-type contact layer 102, the n-type clad layer 103, the n-type light guide layer 104, the n-type superlattice layer 105, the MQW active layer 106, the p-type first light guide layer 107, the p-type second light guide layer 108, the p-type clad layer 109 and the p-type contact layer 110, on the n-type buffer layer 101 by a crystal growth.

FIG. 3 shows a cross-sectional view of the side surface light emitting semiconductor element obtained after carrying out the laminating process.

In step S102, a process of forming a stripe pattern is carried out in which a stripe pattern is formed by SOG (Spin on glass).

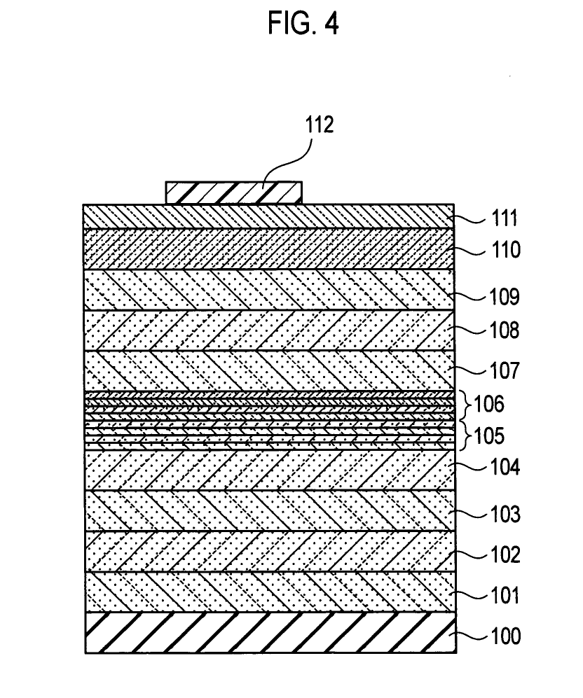

FIG. 4 shows a cross-sectional view of the side surface light emitting semiconductor element in the process of forming the stripe pattern. With reference to FIG. 4, the process of forming the stripe pattern will be specifically described below.

Specifically, in the process of forming the stripe pattern, an SOG material is firstly applied on the p-type contact layer 110. The SOG material is a solution prepared by dissolving silicate compound in an organic solvent.

Secondly, the applied SOG material is baked at approximately 450° C. and an SOG layer 111 containing silicate glass (SiO₂) as a main component is formed.

Thirdly, a resist film is applied on the SOG layer 111 and a resist pattern 112 is formed by photolithography.

Fourthly, an etching is performed on the SOG layer 111 by the resist pattern 112 as a masking pattern. The etching may be a wet-etching utilizing a buffered hydrofluoric acid (BHF) or a dry-etching utilizing a fluorine-based gas (CF₄, SF₆ and the like). Here, a dry-etching that makes it possible to finely cut the resist pattern 112 is preferably performed.

Fifthly, the resist pattern 112 is removed by using an O₂ asher (O plasma), an alkaline solution or the like to form a stripe pattern composed of the remaining SOG layer 111.

In step S103, a process of forming a ridge structure is performed. In this process, a ridge composed of the p-type contact layer 110 is formed using an Induced Coupled Plasma (ICP) etcher.

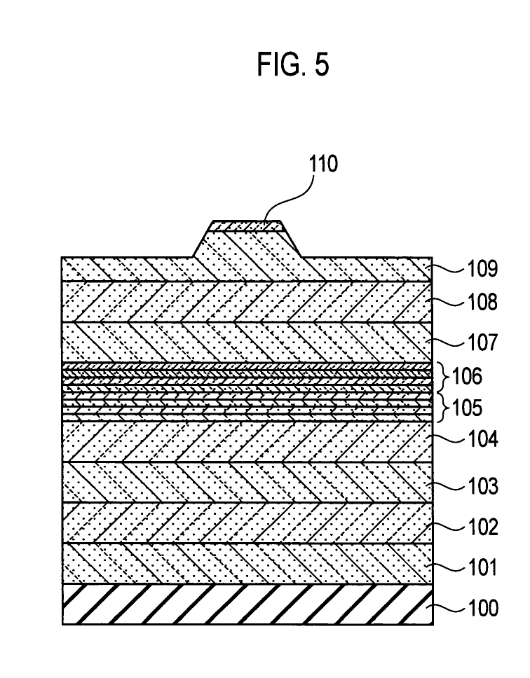

FIG. 5 shows a cross-sectional view of the side surface light emitting semiconductor element in the process of forming the ridge structure. The process of forming the ridge structure is specifically described below with reference to FIG. 5.

Specifically, an etching is firstly performed on the p-type contact layer 110, a part of the p-type clad layer 109, and a part of layers from the p-type contact layer 110 to the n-type contact layer 102 by an ICP etcher, by masking a stripe pattern composed of the SOG layer.

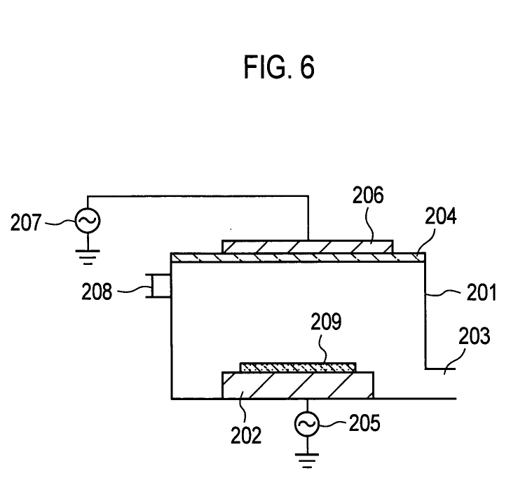

FIG. 6 shows a specific example of the ICP etcher used in such etching. As shown in FIG. 6, the ICP etcher includes a chamber 201, a bottom electrode 202, an exhaust port 203, a quartz plate 204, a high frequency power source 205, an ICP coil 206, an ICP high frequency power source 207 and a gas introduction port 208.

The ICP etcher carries out the etching by using active species (radicals, ions or the like) generated by a high frequency electric power (P_{ICP}) and a high frequency electric power (P_{Bias}). The high frequency electric power (P_{ICP}) is applied to the ICP coil 206 by an ICP high frequency power source 207 to plasmatize a reactive gas. The high frequency electric power (P_{Bias}) is applied to a high frequency power source 205 to introduce the plasmatized reactive species into the etching target material 209. Thus, the etching is performed by damaging the etching target material 209.

Specifically, in the process of forming the ridge structure, the etching target material 209 (in the present embodiment, the side surface light emitting semiconductor element (having a laminated structure) obtained after carrying out step 102) is placed on the ICP etcher, and a first high frequency electric power (P_{ICP} and P_{Bias}) is applied.

Here, by the high frequency electric power mainly applied to the high frequency power source 205, a DC bias voltage (V_DC) is generated on the etching target material 209 (having a laminated structure) placed on the lower electrode 202 in the chamber 201 of the ICP etcher. The degree of damage caused in the layers from the p-type contact layer 110 to the n-type contact layer 102 can be defined by the V_DC. For example, V_DC≧20 V, preferably V_DC≧40 V can cause damage in the p-type contact layer 110 or in the p-type clad layer 109 to obtain the desired effect.

In the process of forming the ridge structure of the present embodiment, the etching is performed on the p-type contact layer 110 composed of GaN, by applying the first high frequency electric power of P_{ICP}=300 W and P_{Bias}=25 W. At this time, the V_DC generated on the etching target material 209 is very small, for example about 10V.

In the process of forming the ridge structure of the present embodiment, the etching is performed on the layers from the p-type contact layer 110 to the n-type contact layer 102, by applying the first high frequency electric power of P_{ICP}=300 W and P_{Bias}=25 W.

In step S104, a process of forming a Schottky barrier is performed. In the process of forming the Schottky barrier, the Schottky barrier 1091 is formed on the top surface of the laminated structure in an area where the ridge structure is not formed (i.e., on the top surface of the p-type clad surface 109 and where the p-type contact layer 110 is etched) by the ICP etcher utilizing an ion impact.

Specifically, in the process of forming the Schottky barrier, the etching target material 209 (in the present embodiment, the side surface light emitting semiconductor element (having a laminated structure) obtained after carrying out the step 103) is placed on the ICP etcher, and the first high frequency electric power (P_{ICP} and P_{Bias}) that is higher than the second frequency electric power (P_{ICP} and P_{Bias}) is applied.

In the process of forming the Schottky barrier of the present embodiment, the etching is performed on the p-type clad layer 109 by applying a second high frequency electric power of P_{ICP}=300 W and P_{Bias}=120 W. At this time, a V_DC as large as about 50V is generated on the etching target material 209. Therefore, ions generated by the electric power of the ICP high frequency power source 207 are accelerated by the V_DC and can collide on the target etching material 209 to cause damage.

In steps S104 and S105, a residual thickness after the etching can be measured by an interferometer utilizing laser. The interferometer can determine the etching depth from the intervals between interference fringes generated by the interference between a reflected wave from the top of the interface and a reflected wave from the bottom of the interface. When the wavelength of the laser to be used is λ, λ/n (n=refraction index of the etching target material) indicates one cycle of the interference.

In step S105, a process of forming an electrode is carried out in which an n-electrode 114 and a p-electrode 113 are formed.

Specifically, an exposed surface of the n-type contact layer 102 formed in step S103 is firstly cleaned with hydrochloric acid. Then, an Al layer, a Ti layer and an Au layer are sequentially laminated on the exposed surface to form the n-electrode 114. The n-electrode 114 may be formed of a multilayer film Al/Ni/Au or Al/Pd/Au by using Ni or Pd layer in place of Ti layer.

Further, at least a part of area on the Schottky barrier 1091 and the top surface of the ridge are cleaned with hydrochloric acid. Then, a Pd layer, and an Au layer are sequentially laminated to form the p-electrode 113. The p-electrode 113 may be formed of a Ni layer and an Au layer, by laminating a Ni layer in place of Pd layer.

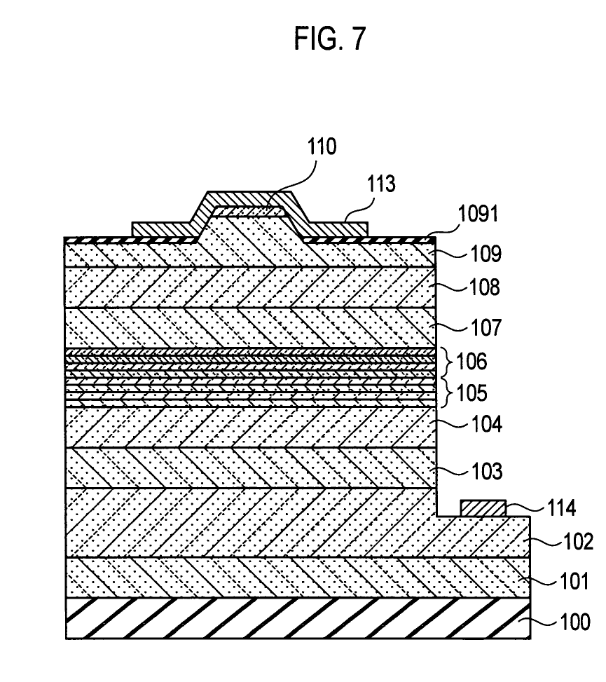

FIG. 7 shows a cross-sectional view of the side surface light emitting semiconductor element obtained after forming the n-electrode 114 and the p-electrode 113.

Secondly, the substrate 100 and n-type buffer layer 101 are ground and the back surface of the n-type contact layer 102 is polished.

Thirdly, the side surface light emitting semiconductor element is subjected to cleavage in its width direction, and the side surface light emitting semiconductor element shown in FIG. 1 can be obtained. The cleavage is performed not to form a mirror surface for obtaining a semiconductor laser element, but to form a side surface light emitting type LED. Therefore, a high accuracy is not required and a small error is acceptable.

### (Operation and Effect of the Side Surface Light Emitting Semiconductor Element According to the Embodiment of the Present Invention)

The side surface light emitting semiconductor element of the present embodiment is provided with a ridge having a striped shape and formed in an upper portion of the laminated structure which includes the p-type clad layer 109 and the MQW active layer 106, a Schottky barrier 1091 formed on a top surface of the laminated structure in an area where the ridge is not formed and the p-type clad layer 109 is exposed. According to this structure, in the ridge structure, removing only a part of an insulation film to be in ohmic contact with the p-electrode 113 is not required. Thus, a production yield can be improved.

The p-type clad layer 109, which is formed of AlₓGa₁₋ₓN (0≦x≦0.5) having a wide band gap energy, is doped with Mg at a concentration equal to or less than 5×10¹⁹ cm⁻³. This reduces the concentration of the holes in the p-type clad layer 109. In other words, it becomes more difficult for the holes to flow from the Schottky barrier 1091 to the p-type clad layer 109, resulting in an increased resistance between the Schottky barrier 1091 and the p-type clad layer 109.

Accordingly, the holes tend to flow only through the ridge in the side surface light emitting semiconductor element. Therefore, a current constriction effect, a current confinement effect and a light confinement effect can be achieved in the ridge, and emitting light from the active layer having a small area can be realized.

Thus, the side surface light emitting semiconductor element which emits light from a local area and has a simple structure and a high production yield can be obtained.

Further, the upper portion of the ridge is the p-type contact layer 110 composed of GaN doped with Mg at a concentration equal to or more than 1×10¹⁹ cm⁻³. Accordingly, the concentration of electrons in the upper portion of the ridge can be increased to further improve the current constriction effect of the ridge.

Additionally, the p-electrode 113 composed of Pd or Ni is provided on at least a part of the Schottky barrier 1091 and on the ridge. This makes it possible to obtain an electrode which easily takes an ohmic characteristic to the p-type clad layer 109 and the p-type contact layer 110. Thus, the holes can easily be flow through the upper portion of the ridge, and the current constriction effect of the ridge can further be improved.

According to the method of manufacturing the side surface light emitting semiconductor element of the present embodiment, the ridge is formed in the upper portion of the laminated structure which includes the MQW active layer 106 and the p-type clad layer 109 composed of AlGaN doped with Mg at a concentration equal to or less than 5×10¹⁹ cm⁻³. Further, an appropriate damage is applied, by performing the dry-etching utilizing the ion impact, on the top surface of the laminated structure in an area where the ridge is not formed and the p-type clad layer 109 is exposed. Thus, an n-type inversion layer (i.e., the Schottky barrier 1091), in which the holes have difficulty in flowing, is formed.

Thus, the resistance between the Schottky barrier 1091 and the p-type clad layer 109 is increased whereby the holes easily flow through only the ridge. Accordingly, the current constriction effect can be obtained in the ridge.

Thus, the side surface light emitting semiconductor element which has a high production yield and emits light from a local area can be manufactured.

The side surface light emitting type LED of the present embodiment can be used with, for example a head mount type display device. The head mount type display device has a shape of a goggle or a helmet. The head mount type display device places displays in front of each of the eyes when it is mounted on a head.

In such a head mount type display device, light emitting semiconductor elements each emitting red, green and blue lights are arranged as a light source having a narrow spectrum. The head mount type display device transmits the light emitted from a light emitting semiconductor element to a human retina via an optical fiber, and forms an image on the retina.

In such head mount type display device, a coupling efficiency between an optical fiber and a light emitting semiconductor element has to be increased. The side surface light emitting type LED of the present embodiment allows light to be emitted from a local area, resulting in improved the coupling efficiency with an optical fiber.

Also, such side surface light emitting type LED does not have a complicated structure and has a high production yield, and therefore is provided as an inexpensive semiconductor light emitting element.

The light emitted from such side surface light emitting type LED is a spontaneous emission light and can therefore reduce an impact on the retina as compared to the light repeatedly amplified by a semiconductor laser element to emit. Therefore, such side surface light emitting type LED is suitable as a light emitting semiconductor element used in a head mount display device.

### OTHER EMBODIMENT

Although the present invention has been described using the aforementioned embodiments, it should not be understood that the descriptions and drawings that are a part of this disclosure limit the present invention. This disclosure will disclose various alternative embodiments, examples and operational technologies to those skilled in the art.

Although, for example, the side surface light emitting type LED is exemplified in the embodiment of the present invention, the present invention is not limited to this and can also be utilized for a side surface light emitting type semiconductor laser element.

As described above, it is obvious that the present invention includes various embodiments and the like which are not described herein. Therefore, the technical scope of the present invention is specified only by constituent features of the invention according to claims which are considered reasonable from the aforementioned description.

### INDUSTRIAL APPLICABILITY

The present invention can provide a side surface light emitting semiconductor element and a method of manufacturing the side surface light emitting semiconductor element, which emit light from a local area and have a high production yield.

1. A side surface light emitting semiconductor element, comprising:
an AlGaN layer doped with Mg at a concentration equal to or less than 5×10¹⁹ cm⁻³;
a ridge having a striped shape and formed in an upper portion of a laminated structure which includes the AlGaN layer and an active layer; and
a Schottky barrier formed on a top surface of the laminated structure in an area where the ridge is not formed and the AlGaN layer is exposed.

2. The side surface light emitting semiconductor element according to claim 1, wherein an upper portion of the ridge is a GaN layer doped with Mg at a concentration equal to or more than 1×10¹⁹ cm⁻³.

3. The side surface light emitting semiconductor element according to claim 1, further comprising:
a metallic layer composed of Pd or Ni, formed on the ridge and on at least a part of the Schottky barrier.

4. A method of manufacturing a side surface light emitting semiconductor element, comprising:
forming a ridge having a striped shape, on an upper portion of a laminated structure which includes an active layer and an AlGaN layer doped with Mg at a concentration equal to or less than 5×10¹⁹ cm⁻³; by performing a dry-etching utilizing an ion impact, and
forming a Schottky barrier, on a top surface of the laminated structure in an area where the ridge is not formed and the AlGaN layer is exposed, by performing the dry-etching utilizing the ion impact.

5. The side surface light emitting semiconductor element according to claim 2, further comprising:
a metallic layer composed of Pd or Ni, formed on the ridge and on at least a part of the Schottky barrier.
